(19) United States
(12) Patent Application Publication
(10) Pub. No.: US 2023/0317871 A1
(43) Pub. Date: Oct. 5, 2023

(54) LIGHT EMITTING DIODE (LED) STRUCTURES FOR A MICROLED DEVICE, AND METHOD FOR PRODUCING AN ARRAY OF LED STRUCTURES

(71) Applicants: The Board of Trustees of the University of Illinois, Urbana, IL (US); Board of Regents, The University of Texas System, Austin, TX (US)

(72) Inventors: Xiuling Li, Austin, TX (US); Clarence Chan, Champaign, IL (US)

(21) Appl. No.: 18/124,132

(22) Filed: Mar. 21, 2023

Related U.S. Application Data
(60) Provisional application No. 63/325,443, filed on Mar. 30, 2022.

(51) Int. Cl. H01L 33/00; H01L 33/32; H01L 33/06; H01L 27/15

(52) U.S. Cl. CPC H01L 33/0025; H01L 33/32; H01L 33/06; H01L 27/156; H01L 33/007

(57) ABSTRACT

Light emitting diode (LED) structures formed by metal-assisted chemical etching for microLED device applications include heterostructure micropillars on a substrate, where each heterostructure micropillar comprises a stack of semiconductor layers separated by heterojunctions. Sidewalls of the heterostructure micropillars are completely or substantially devoid of ion-induced defects. A method of forming an array of LED structures comprises: providing a sample to be etched, where the sample includes a heterostructure stack with metal catalyst regions on a top surface thereof, the heterostructure stack including a plurality of semiconductor layers separated by heterojunctions; exposing the sample to an etching solution or vapor; during the exposure to the etching solution or vapor, optionally illuminating the sample with above-gap radiation; and etching the semiconductor layers in a thickness direction between the metal catalyst regions, thereby forming an array of heterostructure micropillars, each covered with one of the metal catalyst regions.

### RELATED APPLICATIONS

The present patent document claims the benefit of priority under 35 U.S.C. § 119(e) to U.S. Provisional Patent Application No. 63/325,443, which was filed on Mar. 30, 2022, and is hereby incorporated by reference in its entirety.

### FEDERALLY SPONSORED RESEARCH AND DEVELOPMENT

This invention was made with government support under 1809946 awarded by the National Science Foundation. The government has certain rights in the invention.

### TECHNICAL FIELD

The present disclosure is related generally to semiconductor device fabrication and more particularly to a metal-assisted chemical etching method to form heterojunction structures for light emitting diodes (LEDs).

### BACKGROUND

LED devices have a wide range of applications, including solid state lighting for interior and exterior illumination both for consumer and business applications, display applications (mobile electronic devices, computers, televisions), and as other illumination applications, such as individual indicator lights and for lighting in automotive and industrial applications. Additional potential applications include visible light communication and new display applications for augmented, mixed, virtual reality (AR/MR/VR) devices.

There is a drive to shrink LED devices to ever-smaller footprints to form microLED and sub-microLED devices to enable applications where a smaller illumination source is required. In displays, the use of a smaller single device illumination defining a pixel (self-emissive) as opposed to a larger device illumination with separate smaller filters (such as a liquid crystal) defining a pixel is desired for a number of visual qualities, such as wider viewing angles, higher contrast and faster response. Atop of the aforementioned desirable qualities of LEDs as a self-emissive illumination source, further size reduction to microLEDs allow for a larger number of devices (and hence pixels) in a fixed area. As an example, AR/MR/VR applications require a significantly pixel density (commonly quantified by pixels per inch or PPI) than current display applications such as mobile phone displays. Human vision can distinguish up to 300 PPI at a distance of 2.5 ft away from a display while an individual with 20/20 vision can distinguish up to 720 PPI at a distance of 1 ft away from a display. In the case of AR/MR/VR applications (head-mounted display format) with a significantly shorter separation between the human eye and display, it is expected that increasing PPI from 400 to 1000 may be perceivable in the proposed use case. Additionally, microLED devices are expected to possess significantly higher brightness and can enable displays with higher ambient contrast required for improved outdoor viewing compared to existing LCD and OLED technologies. From a production standpoint, the impetus for device scaling to microLEDs is to increase the number of chips per wafer to reduce the cost of microLEDs in a bill of materials. As an example, in lower PPI applications such as next generation high resolution displays for television, the microLED device dimension must be reduced to less than 10 μm for cost effectiveness.

Group III (Al, Ga, In, etc.)-nitride heterojunction structures (or heterostructures) are widely used in modern light emitting diodes. Currently, fabrication of III-nitride heterojunction structures in devices utilizes plasma-based reactive ion etching (RIE) to etch semiconductor material layers on a large substrate to form individual LED devices (mesas/structures) on the substrate. The use of RIE processes are detrimental to LED device efficiency, primarily via device sidewall damage during etching, and increasingly so when producing ever-smaller microLED devices. The low efficiency of current microLED devices in practice presents a barrier of entry compared to larger LEDs and competing OLED device technologies, which theoretically have a lower efficiency than a damage-free microLED device.

### BRIEF SUMMARY

LED structures formed by metal-assisted chemical etching for microLED device applications are described in this disclosure.

The LED structures include heterostructure micropillars on a substrate, where each heterostructure micropillar comprises a stack of semiconductor layers separated by heterojunctions. Sidewalls of the heterostructure micropillars are completely or substantially devoid of ion-induced defects.

A method of forming an array of LED structures comprises: providing a sample to be etched, where the sample includes a heterostructure stack with metal catalyst regions on a top surface thereof, the heterostructure stack including a plurality of semiconductor layers separated by heterojunctions; exposing the sample to an etching solution or vapor; optionally, during the exposure to the etching solution or vapor, illuminating the sample with above-gap radiation; and etching the semiconductor layers in a thickness direction between the metal catalyst regions, thereby forming an array of heterostructure micropillars, each covered with one of the metal catalyst regions.

### BRIEF DESCRIPTION OF THE DRAWINGS

FIG. 1A is a scanning electron microscope image of an array of heterostructure micropillars formed by metal-assisted chemical etching.

FIG. 1B is a schematic of a single as-etched heterostructure micropillar showing an exemplary arrangement of semiconductor layers with AlGaN/GaN heterojunctions.

FIG. 1C is a scanning electron microscope image of one of the heterostructure micropillars of FIG. 1A.

FIG. 2A shows a “device-ready” LED structure formed by metal-assisted chemical etching.

FIGS. 2B-2D show the formation of exemplary microLED devices from the LED structure of FIG. 2A.

FIG. 3A shows an exemplary heterostructure stack including a metal catalyst region thereon prior to metal-assisted chemical etching.

FIGS. 3B-3C show a partially etched and fully etched heterostructure micropillar, respectively.

FIG. 3D shows a scanning electron microscope image of the heterostructure micropillar shown schematically in FIG. 3C.

FIGS. 4A and 4B illustrate an example of providing a heterostructure stack ready for metal-assisted chemical etching.

FIG. 4C is a schematic of the heterostructure micropillars formed upon etching the heterostructure stack of FIG. 4B.

FIGS. 5A-5C illustrate another example of providing a heterostructure stack ready for metal-assisted chemical etching.

FIG. 5D is a schematic of the heterostructure micropillars formed upon etching the heterostructure stack of FIG. 5C.

FIG. 6A is a schematic of an exemplary metal-assisted chemical etching process.

FIG. 6B illustrates the mechanism of metal-assisted chemical etching for an exemplary III-nitride sample.

FIG. 7A illustrates a heterostructure stack including alternating layers of AlₓGa₁₋ₓN and n-GaN on a sapphire substrate with x=0.14 in this example.

FIG. 7B shows a scanning electron microscope image of a portion of an array of heterostructure micropillars formed by etching the heterostructure stack shown in FIG. 7A.

FIG. 7C shows a close-up image of a single heterostructure micropillar from the array shown in FIG. 7B.

FIG. 8A is a schematic of a metal catalyst region including a multilayer structure with a catalyst layer or a charge transfer or adhesion layer.

FIG. 8B shows scanning electron microscope images of a GaN micropillar etched using a metal catalyst region including only a ruthenium (catalyst) layer.

FIG. 8C shows scanning electron microscope images of a GaN micropillar formed using metal catalyst region including a ruthenium (catalyst) layer on a tantalum (charge transfer) layer.

FIGS. 9A-9H illustrate an exemplary process flow to produce heterostructure micropillars from a heterostructure stack that undergoes flip bonding prior to etching.

FIGS. 10A-10D illustrate an exemplary process flow where reactive ion etching is combined with metal-assisted chemical etching to address the challenges of etching p-type semiconductor layers.

FIGS. 11A-11E illustrate another exemplary process flow where reactive ion etching is combined with metal-assisted chemical etching to address the challenges of etching p-type semiconductor layers.

FIGS. 12A-12D illustrate metal assisted chemical etching, first using an illumination energy at or above all of the bandgaps in the heterostructure stack, and then using an optical filter to filter out shorter wavelengths in order to achieve selective etching of only the lower bandgap semiconductor layers.

### DETAILED DESCRIPTION

Described in this disclosure is the application of metal-assisted chemical etching to fabricate LED structures comprising heterostructure micropillars for microLED device applications.

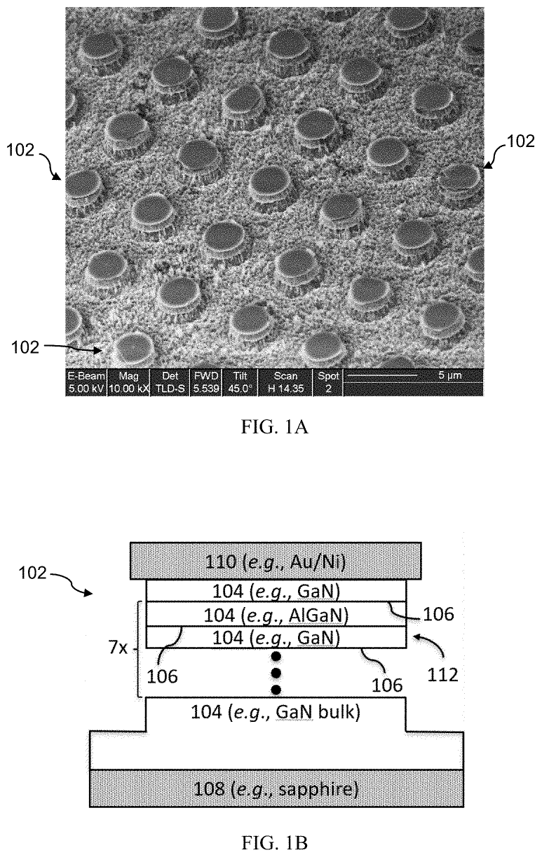

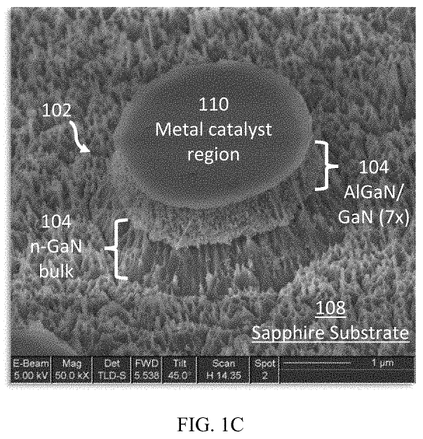

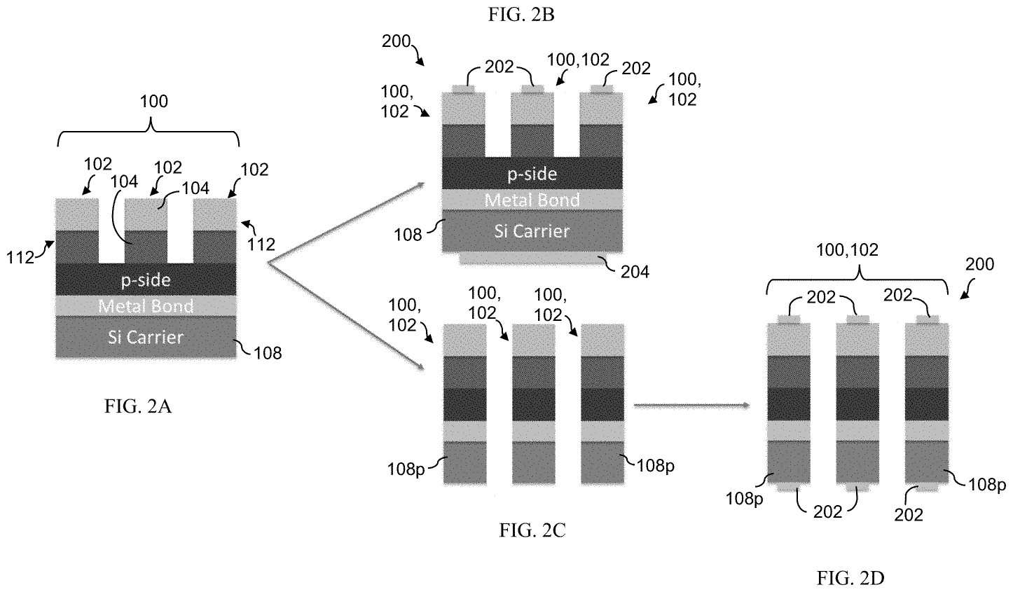

FIG. 1A shows a scanning electron microscope (SEM) image of an array of heterostructure micropillars 102 formed by metal-assisted chemical etching. Referring to the schematic of FIG. 1B, each heterostructure micropillar 102 includes a stack of semiconductor layers 104 separated by heterojunctions 106. The term heterojunction refers to an interface between semiconductor materials of dissimilar chemical composition, and thus the stack of heterstructure micropillars 102 includes semiconductor layers 104 of differing compositions. In this example, the semiconductor layers 104 include alternating layers of GaN and AlGaN, but the layers 104 are not limited to these semiconductor materials. Generally speaking, each heterostructure micropillar 102 may include various semiconductor materials stacked sequentially atop one another and each semiconductor layer 104 may be doped p-type (hole-rich), n-type (electron-rich) or unintentionally-doped (electron majority carrier). The micropillars 102 may be supported on a substrate 108, which in this example is a growth substrate. Because the SEM images of FIGS. 1A and 1C and the associated micropillar schematic of FIG. 1B show as-etched structures, each micropillar 102 is topped with a metal catalyst region 110, which is a remnant of the metal-assisted chemical etching process used for fabrication. The metal catalyst regions 110 may be removed from the micropillars 102 after etching to form “device-ready” LED structures 100, as illustrated in FIG. 2A and discussed further below.

Returning to FIGS. 1A and 1B, each heterostructure micropillar 102 may take the form of a mesa with a height defined by the stack of semiconductor layers 104 (e.g., by the thickness of each layer and the number of layers) and a width or diameter defined by the metal-assisted chemical etching process described below. Importantly, sidewalls 112 of the heterostructure micropillars 102 are substantially or completely devoid of ion-induced defects. In other words, the sidewalls 112 of the heterostructure micropillars 102 may be substantially or completely devoid of surface states, point defects such as vacancies, altered stoichiometry, changes in crystallinity, and/or other lattice defects. It is understood that “completely devoid” of ion-induced defects means that the sidewalls 112 do not include any such defects or do not include a measurable amount of such defects. “Substantially devoid” of ion-induced defects means that the sidewalls 112 include a minuscule amount of such defects that does not negatively impact the efficiency of the LED structures 100. The absence or substantial absence of ion-induced defects in the sidewalls 112 may be confirmed by photoluminescence (PL) and/or electroluminescence (EL) intensity. In contrast, structures produced by reactive ion etching (RIE) may include ion-induced defects extending up to 500-600 nm into the structures, and thus the RIE structures may require additional post-etching process step(s) to remove ion-induced sidewall damage. Such process steps may significantly reduce the size of the etched structures, which are intended to have microscale areal dimensions. The heterostructure micropillars 102 described in this disclosure may have an areal size, or footprint on the substrate, which is close in size (+/−10% or +/−20%) to the metal catalyst regions, since additional post-etching steps are not required to remove ion-damaged regions that extend deep into the structures. The sidewalls 112 of the heterostructure micropillars 102 may include an etched surface roughness of about 40 nm or less, or about 20 nm or less, and typically about 1 nm or higher, or about 5 nm or higher.

Some or all of the semiconductor layers 104 may comprise wide-bandgap semiconductor layers having a bandgap above about 3 eV. Because the heterostructure micropillars 102 include semiconductor layers 104 of differing compositions, it is understood that each of the heterostructure micropillars 102 may include a range of bandgaps, e.g., from about 1.6 eV to about 6 eV, from about 1.6 eV to about 4.5 eV, from about 3 eV to about 6 eV, or from about 3 eV to about 4.5 eV. In some examples, the semiconductor layers 104 may include two or more group III-nitride semiconductors, that is, two or more semiconductor materials that include nitrogen and at least one element from group 3A of the periodic table (e.g., boron, aluminum, gallium, indium), such as gallium nitride (GaN), aluminum gallium nitride (AlₓGa₁₋ₓN, or AlGaN), indium gallium nitride (InₓGa₁₋ₓN or InGaN), aluminum indium gallium nitride (or indium gallium aluminum nitride) (InₓGa_{y}Al_{1-x-y}N, or InGaAlN), where 0<x<1 and 0<y<1. As indicated above, group III-nitride heterojunction structures are widely used in LEDs. The semiconductor layers 104 may include other semiconductors, such as gallium oxide (Ga₂O₃), aluminum gallium oxide (AGO), other group III-nitride semiconductors (e.g., aluminum scandium nitride (AlₓSc₁₋ₓN, or AlScN), and/or aluminum boron nitride (AlₓB₁₋ₓN, or AIBN), where 0<x<1 and 0<y<1), and/or III-V semiconductors based on InP, GaP, InAs, and/or GaAs, such as AlInGaP. The heterostructure micropillars 102 may include one or more multiple quantum wells (MQWs) 114, each of which may include, in one example, a semiconductor layer 104 comprising indium gallium nitride on a semiconductor layer 104 comprising gallium nitride (InGaN/GaN), with an aluminum gallium nitride (AlGaN) barrier layer. The MQWs 114 may function as active regions for the LED structures 100. The semiconductor layers 104 may include p-type dopants, n-type dopants, and/or no intentional dopants. Each heterostructure micropillar 102 may be configured to emit visible (e.g., red, green, or blue) or ultraviolet (UV) light.

Each of the heterostructure micropillars 102 may include from 3 to 30 of the semiconductor layers 104. A height-to-width aspect ratio of the heterostructure micropillars 102 may be as large as 10, in some examples. Due to the drive to reduce feature sizes, each heterostructure micropillar 102 may have a maximum width or diameter no greater than about 20 μm, no greater than about 10 μm, or no greater than about 5 μm. Typically, the maximum width or diameter is at least about 1 μm, or at least about 3 μm.

The substrate 108 may comprise a glass, polymer, metal, insulator (e.g., sapphire) and/or semiconductor. In some examples (e.g., depending on the application), the substrate 108 may be flexible. The substrate 108 may be a growth substrate or a carrier substrate to which the semiconductor layers 104 are transferred prior to etching or to which the heterostructure micropillars 102 are transferred after etching. A microLED may be formed from the LED structures described above.

The heterostructure micropillars 102 may be arranged in an array on the growth or carrier substrate 108. The array may include at least about 100 heterostructure micropillars 102, at least about 500 heterostructure micropillars 102, or at least about 1000 heterostructure micropillars 102, and in some examples the array may include up to or over 10,000 heterostructure micropillars 102, or up to over 100,000 heterostructure micropillars 102. In some examples, the array may be an ordered array, as shown in FIG. 1A.

A long axis of each of the heterostructure micropillars 102 may be oriented substantially normal to the substrate 108. Also or alternatively, the semiconductor layers 104 may be oriented substantially parallel to the substrate 108. In some examples, the sidewalls 112 of the heterostructure micropillars 102 may comprise a finite slope with respect to the substrate 108. For example, the micropillars 102 may have a cone shape with slanted, as opposed to vertical, sidewalls 112.

FIGS. 2B and 2C show examples of microLED devices 200 formed from the “device ready” LED structures 100 of FIG. 2A. As described above, the LED structures 100 comprise an array of heterostructure micropillars 102 on a substrate 108 (shown as a Si carrier in this schematic), where each heterostructure micropillar 102 includes a stack of semiconductor layers 104, and where sidewalls 112 of the heterostructure micropillars 102 are substantially devoid of ion-induced defects. In FIG. 2B, the LED structures 100 further comprise an electrical contact 202 formed on a top surface of each of the heterostructure micropillars 102 and a common electrical contact 204 formed on a bottom surface of the substrate 108. Alternatively, in FIG. 2C, the LED structures 100 are separated such that the heterostructure micropillars 102 no longer share the same substrate, and each heterostructure micropillar 102 is instead isolated on a substrate portion 108p. Each LED structure 100 in this case includes an electrical contact 202 formed on a top surface of each of the heterostructure micropillars 102 and on a bottom surface of each of the substrate portions 108p, as shown in FIG. 2D. The electrical contacts 202,204 may include n-type contacts in contact with n-type material from the heterostructure micropillars 102 and p-type contacts in contact with p-type material from the heterostructure micropillars 102.

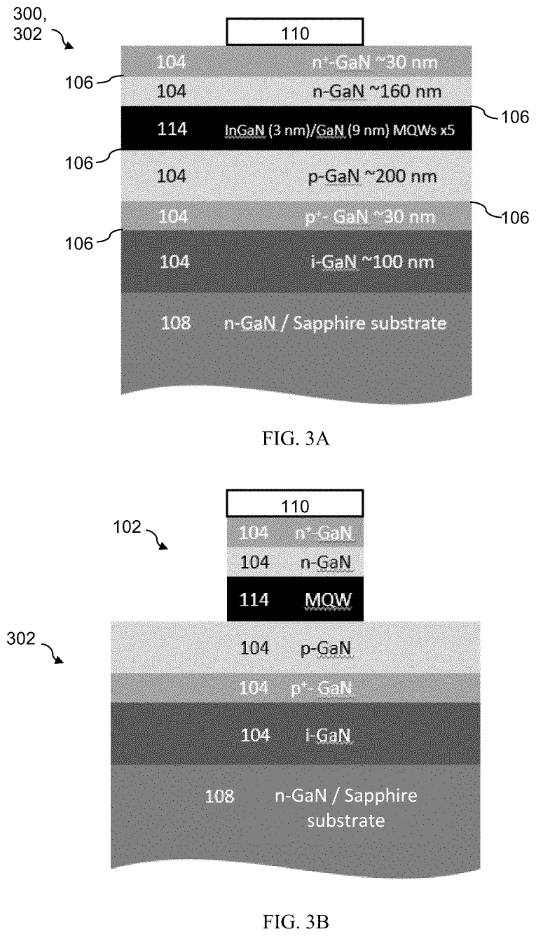

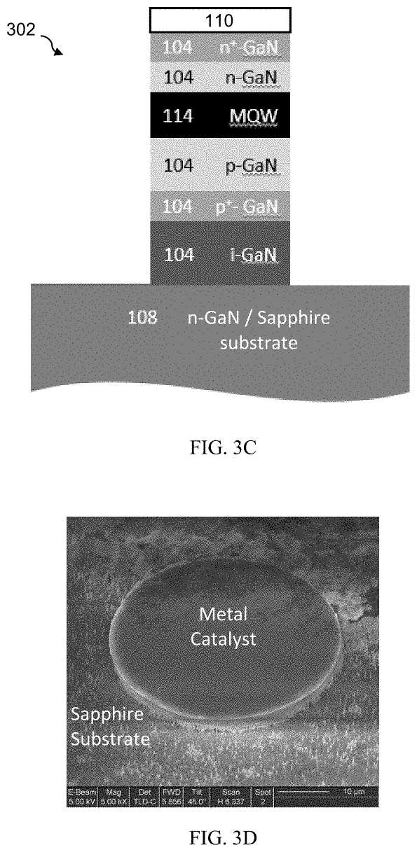

A method of forming an array of LED structures 100 is now described. Referring to FIG. 3A, the method includes providing a sample 300 to be etched, where the sample 300 comprises a heterostructure stack 302 with metal catalyst regions 110 on a top surface thereof (only one metal catalyst region 110 is shown in this schematic). The heterostructure stack 302 includes a plurality of semiconductor layers 104 separated by heterojunctions 106. To illustrate all doping types, in this example the semiconductor layers include n-type (n+ and n), p-type (p and p+) and intrinsic (i) GaN sandwiching five repeating MQWs, which include InGaN on GaN, on a n-GaN/sapphire substrate. Layer thicknesses for this particular sample 300, which has been fabricated experimentally, are indicated in the figure. Post-growth photoluminescence measurements confirm the presence of the MQW structure needed for LEDs. The semiconductor layer structure in this example is generally representative of a flip-bonded LED, although the etching method is not limited to any particular semiconductor layer structure or composition.

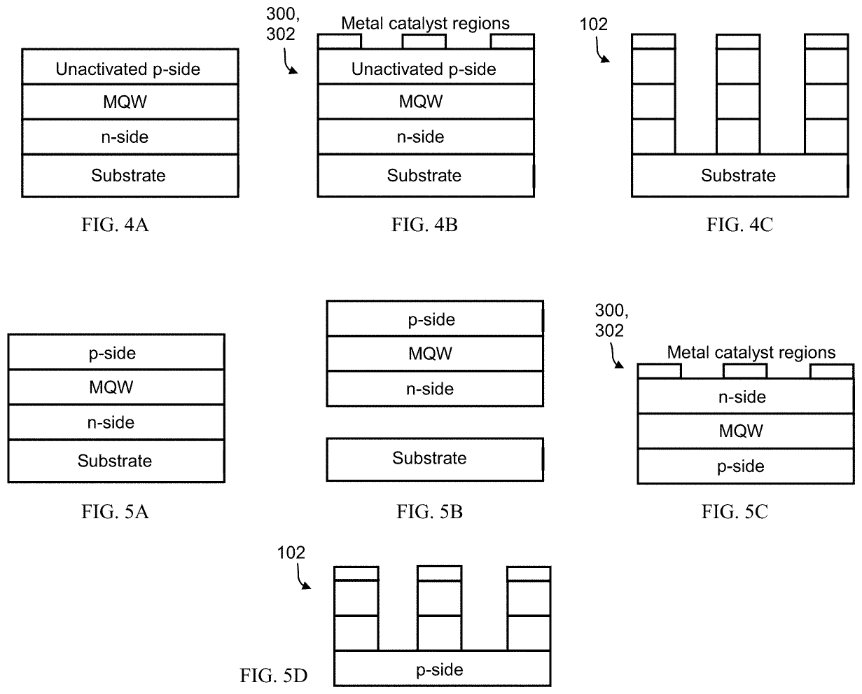

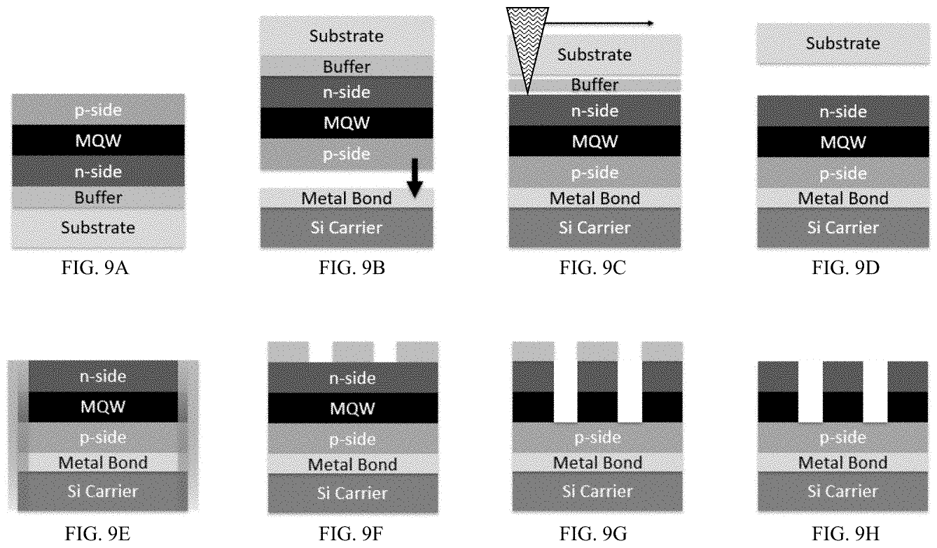

Providing the sample 300 may entail, in one example, epitaxially growing the semiconductor layers (e.g., n-type layers, MQW structures, and unactivated p-type layers) on a growth substrate, as shown schematically in FIG. 4A, depositing a metal catalyst layer on a top layer of the semiconductor layers, and patterning the metal catalyst layer to form the metal catalyst regions, as illustrated in FIG. 4B. For flip-bonded LEDs, providing the sample 300 may entail epitaxially growing the semiconductor layers (e.g., n-type layers, MQW structures, and activated p-type layers) on a growth substrate, as illustrated in FIG. 5A, removing the heterostructure stack from the growth substrate by epitaxial lift-off, as shown in FIG. 5B, flipping the heterostructure stack such that a bottom layer of the semiconductor layers (n-type layer) becomes a top layer, depositing a metal catalyst layer on the top layer, and patterning the metal catalyst layer to form the metal catalyst regions, as illustrated in FIG. 5C. Processing of a flip-bonded LED is described in greater detail below in reference to FIGS. 9A-9H.

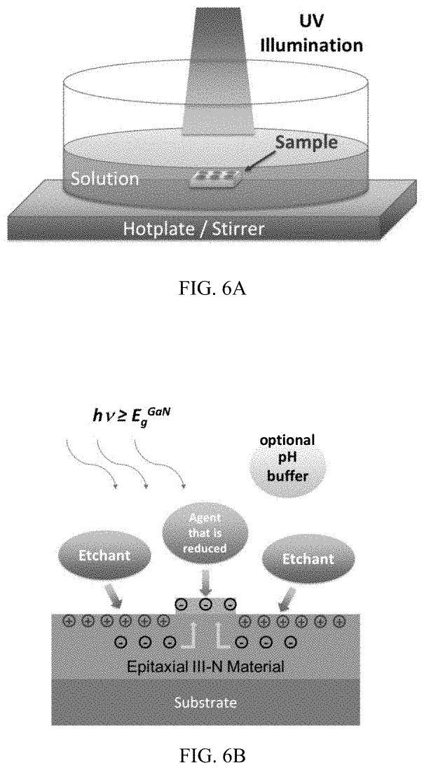

To initiate etching, the sample 200 is exposed to an etching solution or vapor. In some examples, the sample 200 is illuminated with above-gap radiation during the exposure, as illustrated in FIG. 6A for a liquid-phase etching solution, where “above-gap” radiation has a photon energy as high as and/or higher than bandgaps of the semiconductor layers to be etched. Advantageously, metal-assisted chemical etching is a plasma-free process and thus ion-induced defects can be avoided. The etching solution contains an oxidant along with an acid or a base to selectively oxidize and dissolve portions of the semiconductor substrate. Photo-enhanced, catalyst-assisted chemical reactions may occur, as illustrated in FIG. 6B for a III-nitride material such as GaN, where above-bandgap photons promote the generation of e−/h+ and enhance the etch rate. Consequently, the semiconductor layers are etched in a thickness direction between the metal catalyst regions, as illustrated in FIGS. 4C and 5D. It is contemplated that the method may include using two or more different etching solutions or vapors in sequence depending on the semiconductor materials in the heterostructure stack. For the exemplary sample of FIG. 3A, a partially etched heterostructure micropillar 102 is illustrated in FIG. 3B, and a fully etched heterostructure micropillar 102 is shown in FIG. 3C. Challenges with etching p-type semiconductor layers 104 are discussed further below. FIG. 3D shows a SEM image of the heterostructure micropillar 102 of FIG. 3C.

The oxidant utilized in the etching solution may comprise a peroxydisulfate ion, K₂S₂O₈, and/or CuSO₄. Suitable acids for the etching solution may include HF, H₂SO₄, and/or HCl, and suitable bases may include hydroxide bases, such as KOH, NaOH, NH₄OH, and/or tetramethylammonium hydroxide (TMAH). When a base is employed in the etching solution or vapor, a pH buffer such as Na₂CO₃ or Na₃PO₄ may also be used. For the exemplary layer structure illustrated in FIG. 3A, the etching solution was based on KOH chemistry, and HCl chemistry has also been demonstrated. Typically, a molar ratio of the acid or the base (the etchant) to the oxidant is in a range from 12:1 to 1:12, from 1:1 to 1:12, and/or from 1:6 to 1:12. In some examples, a molar ratio of the base to the oxidant may be in a range from 12:1 to 1:60. The ratio of the etchant versus the oxidant may control the level of chemical attack, via the etchant, and the level of photocarrier consumption by redox reaction, via the oxidant. The ratio of etchant to the oxidant may determine vertical etch anisotropy and the absolute concentration under a fixed ratio may determine the etch rate. The etching solution concentration, or molarity of the components of the etching solution, may also influence etching. Non-limiting examples of etching solution concentrations include from 7.5 mM to 150 mM of oxidant and from 150 mM down to 0.625 mM of the etchant, where the etchant is unity down to 1/12 of oxidant concentration. The polarity of the substrate, e.g., for GaN, whether the substrate is Ga or N polar, can additionally enhance or inhibit etching. To promote etching, the sample may be heated to a temperature in a range from about 30° C. to about 95° C., or higher if desired, e.g., by placing the sample in thermal contact with a hot plate or other conductive heat source, as illustrated in FIG. 5A, or by carrying out the etching process in a furnace or other temperature-controlled environment. Preferably, the etch rate is in a range from about 20 nm/min to about 800 nm/min, from about 100 nm/min to about 800 nm/min, or from about 20 nm/min to about 300 nm/min.

Because the micropillars 102 comprise semiconductor layers 104 of differing compositions and bandgaps, it is advantageous if not essential that the above-gap radiation which may be employed during etching has a photon energy as high as and/or higher than the bandgaps of all of the semiconductor layers to be etched. The above-gap radiation may comprise above-gap visible (1.5 eV to less than 3 eV) and/or UV (3 eV to 100 eV) radiation. Some or all of the semiconductor layers may comprise wide bandgap semiconductor layers having a bandgap above about 3 eV. Typically, to etch semiconductor layers having bandgaps in a range from about 1.6 eV to about 4.5 eV, the sample may be exposed to an etching solution, whereas etching of semiconductor layers having bandgaps above 4.5 eV may entail exposing the sample to an etching vapor. The intensity and wavelength of the illumination may affect photocarrier generation in the semiconductor layers as well as produce UV-induced chemical changes to the etching solution. Typical intensity levels for the illumination may be from about 10 mW/cm² to about 30 W/cm². It is contemplated that the composition of the etching solution (e.g., molar ratio of acid or base to oxidant) and/or etching conditions (e.g., photon energy or intensity) may be varied during etching as different semiconductor layers are encountered in the stack, in order to optimize the etch rate for each material.

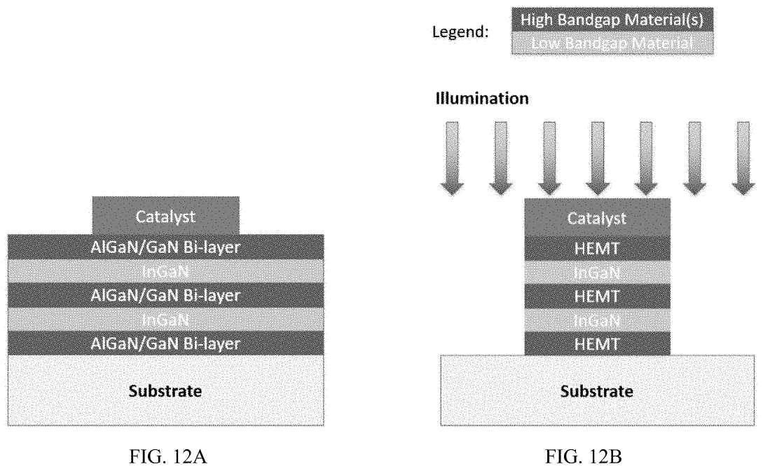

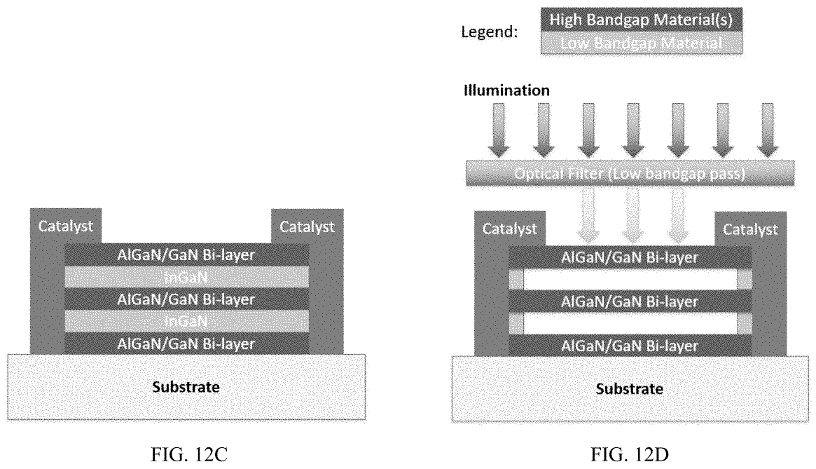

In some examples, the above-gap radiation may have a photon energy as high as and/or higher than bandgaps of only some of the semiconductor layers, such that selective etching of the semiconductor layers may occur. That is, the energy (inverse wavelength) of the radiation impinging upon the heterostructure stack may be controlled to be above the bandgap(s) of only some of the semiconductor layers, such that lower bandgap semiconductor layers are selectively etched and higher bandgap semiconductor layers are not etched, as illustrated in FIGS. 12A-12D. In particular, FIGS. 12A and 12B illustrate metal-assisted chemical etching as described above to define a heterostructure micropillar (or mesa), where all layers are etched, and FIGS. 12C and 12D illustrate possible additional process steps to carry out selective etching, including removal of the (original) metal catalyst region and formation of new metal catalyst regions extending along the sidewalls (FIG. 12C), followed by selective metal-assisted chemical etching with either a different light source or the same light source with the addition of an optical filter (FIG. 12D). In this example, the optical filter (“low bandpass”) allows only longer wavelengths to reach the semiconductor layers, such that only the lower bandgap semiconductor (InGaN in this example) layers undergo etching.

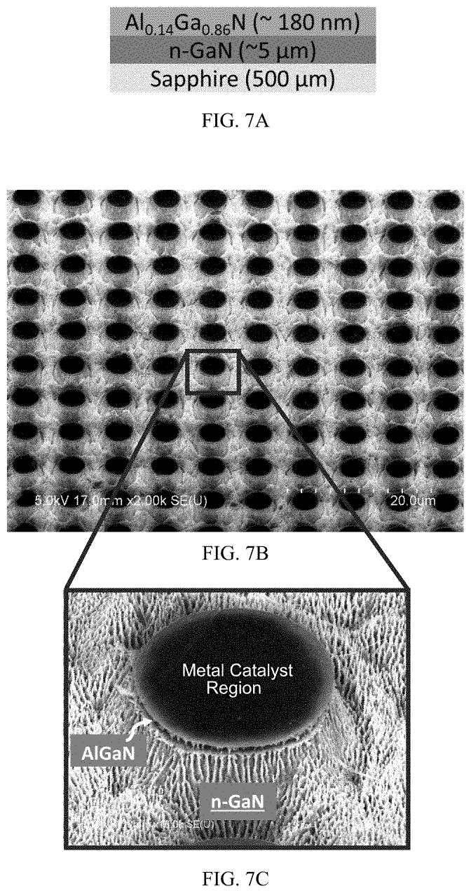

In addition to the semiconductor layer structure illustrated in FIGS. 3A-3D, alternating layers of AlₓGa₁₋ₓN and n-GaN on a sapphire substrate have been successfully etched with x up to 0.2 (e.g, x=0.14, 0.16, 0.2) to form large arrays of heterostructure micropillars (e.g., up to 5 mm×5 mm arrays containing over 550,000 heterostructure micropillars). Larger and/or more dense arrays (e.g., including over 600,000 heterostructure micropillars) are also possible. A schematic of the stack of semiconductor layers is shown in FIG. 7A, and SEM images of a portion of the array and a close-up view of a single heterostructure micropillar are shown in FIGS. 7B and 7C. In the example of FIGS. 1A and 1B, x=0.16 is utilized with seven pairs of AlGaN/GaN heterojunctions, demonstrating that superlattices and the underlying GaN can be successfully etched.

Advantageously, the etching solution or vapor is replenished during etching since the oxidant can degrade over time, and the degradation may be accelerated by exposure to UV light. Thus, the sample may be exposed to a flow of the etching solution or vapor. For example, the vessel shown in FIG. 6A which contains the etching solution may be configured for replenishment of the etching solution, e.g., the vessel may include an inlet for continuous or intermittent flow of the etching solution into the vessel and an outlet for continuous or intermittent removal of (spent) etching solution from the vessel. The oxidant and acid/base which make up the etching solution may be premixed and flowed together into the vessel, or they may be delivered into the vessel separately and then mixed just prior to exposure to the sample. Typically, etching with a liquid-phase etchant takes place in air, although a controlled environment may be used. For example, liquid-phase etching can be carried out in a nitrogen-purged or air-tight enclosure. Typically, etching with a vapor-phase etchant takes place in a controlled environment, such as a vacuum chamber. With vapor phase etching, the oxidant and base/acid can be readily independently controlled, including the flow rate, injection time with synchronous and asynchronous injection, substrate temperature, and chamber pressure/partial pressure, as described for example in U.S. Pat. No. 10,748,781, issued Aug. 18, 2020, to Xiuling Li, et al., which is hereby incorporated by reference in its entirety.

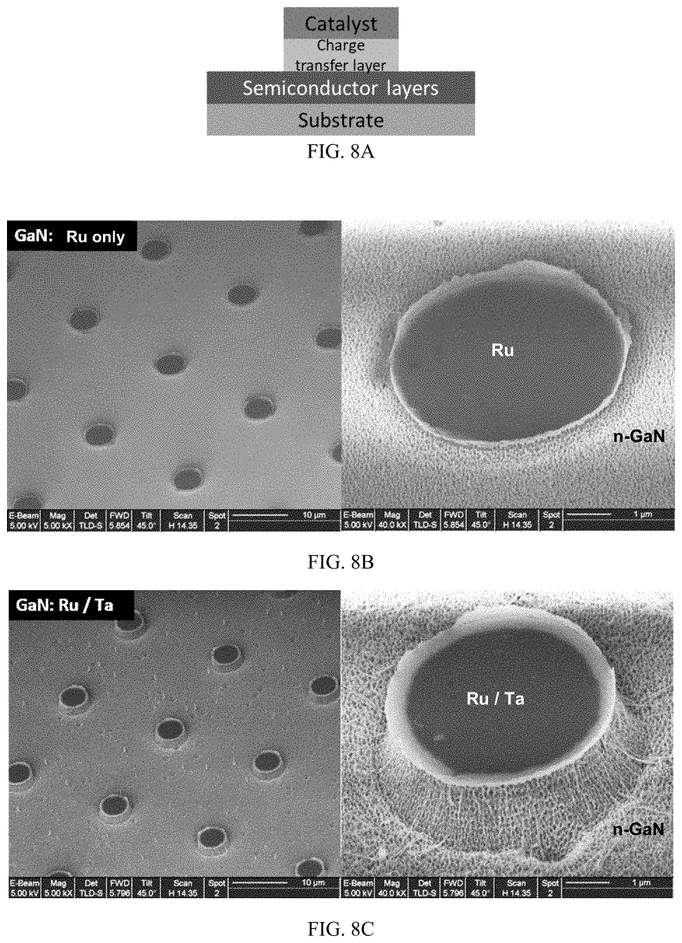

The metal catalyst regions may comprise one or more metals selected from the group consisting of: platinum, gold, nickel, titanium, palladium, rhodium, ruthenium, silver, tantalum, zirconium, tungsten, iridium, molybdenum, hafnium, cobalt, tin, and chromium. As illustrated in FIG. 8A, the metal catalyst regions may in some examples have a multilayer structure including a catalyst layer on a charge transfer or adhesion layer. For example, the catalyst layer may comprise platinum, gold, and/or ruthenium, and the charge transfer or adhesion layer may comprise titanium, nickel, chromium, and/or tantalum. In experiments in which n-GaN undergoes metal-assisted chemical etching with metal catalyst regions comprising a Ru catalyst layer on a Ta charge transfer layer, there is an order of magnitude increase in the etch rate of the n-GaN compared to etching using only a Ru metal catalyst, as can be seen by comparing the images of FIGS. 8B and 8C. Since the heterostructure micropillars 102 formed by etching are covered with the metal catalyst regions 110, the method may further include, after forming the array of heterostructure micropillars 102, removing the metal catalyst regions 110 to facilitate use of the heterostructure micropillars in microLED applications.

A substrate (either a growth substrate or a carrier substrate) supports the heterostructure stack during etching. The heterostructure micropillars may remain on the substrate after etching for further processing to form a microLED device, or they may be transferred to a different substrate after etching to undergo the further processing, which may include, for example, patterning contacts for electrical connection to the heterostructure micropillars (e.g., as illustrated in FIGS. 2B and 2D). The substrate may comprise a glass, polymer, metal, and/or semiconductor. For some microLED applications, the substrate may be flexible.

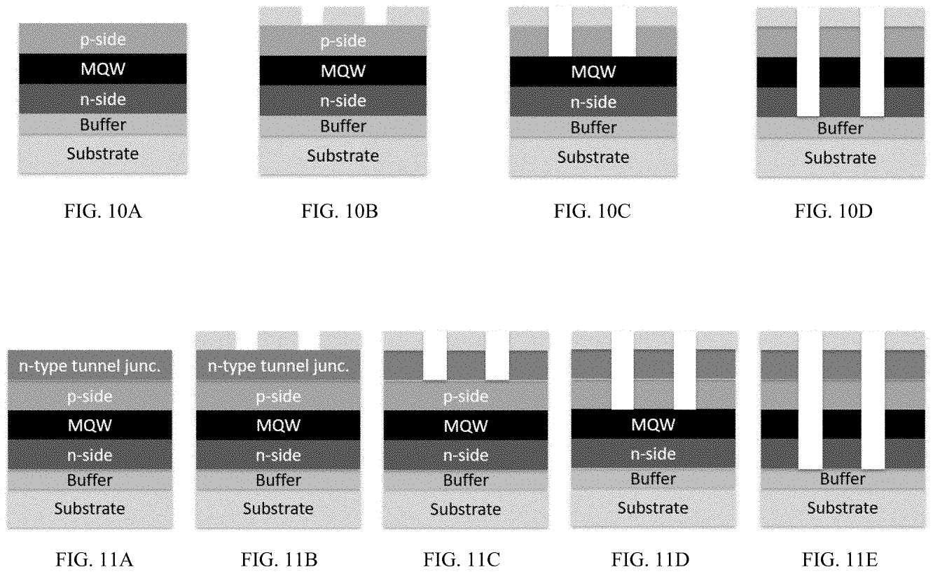

In the process flow shown in FIGS. 4A-4C, prior to etching, the top layer of the semiconductor layers may include an un-activated p-type dopant. Accordingly, after removing the metal catalyst regions, the heterostructure micropillars may be thermally annealed to activate the p-type dopant. In examples where the top layer or a middle layer of the semiconductor layers includes a p-type dopant (activated), the method may further include, during the exposure of the sample to the etchant solution or vapor, selectively applying a bias to the semiconductor layers using an external electrode to enhance the metal-assisted chemical etching process. Alternatively, as discussed below in reference to FIGS. 10A-11E, a different etching method, such as reactive ion etching or chemical etching, may be employed in conjunction with metal-assisted chemical etching to etch through the p-type semiconductor layer(s) (e.g., p-type GaN), which is notoriously difficult to etch using metal-assisted chemical etching.

In other examples, such as the flip-bonded structure used in the process flow shown in FIGS. 5A-5D, the top layer may be an n-doped or not intentionally doped semiconductor layer which is amenable to metal-assisted chemical etching. FIGS. 9A-9H provide a more detailed look at an exemplary process flow for metal-assisted chemical etching of a flip-bonded structure. FIG. 9A shows the starting heterostructure stack which includes different semiconductor layers on a growth substrate, such as sapphire. FIG. 9B shows flip-bonding of the heterostructure stack to a carrier substrate, in this case, silicon (Si), where a metal bond layer is included between the heterostructure stack and the Si carrier. FIG. 9C shows detachment of the growth substrate using a laser lift-off process, as known in the art, and in FIG. 9D, the growth substrate is removed from the heterostructure stack. FIG. 9E illustrates an optional step of passivating the substrate sidewall to protect the metal bond layer during etching. In FIG. 9F, a metal catalyst layer is deposited and patterned to form the metal catalyst regions on top of the heterostructure stack. FIG. 9G illustrates metal-assisted chemical etching to form the heterostructure micropillars, and FIG. 9H illustrates removal of the metal catalyst regions, if needed, to form contact-ready LED structures.

FIGS. 10A-10D and FIGS. 11A-11E provide exemplary process flows where reactive ion etching (RIE) is combined with metal-assisted chemical etching to address the challenges of etching p-type semiconductor layers. FIG. 10A shows a heterostructure stack including p-type semiconductor layer(s) (“p-side”) as the top-most layer(s). In FIG. 10B, a metal catalyst layer is patterned to form metal catalyst regions, which may function as a RIE mask layer in an initial etching step. FIG. 10C shows etching of the p-type semiconductor layer(s), which are typically thin (nanoscale) layers, using RIE. Once the p-type semiconductor layer(s) have undergone RIE, metal-assisted chemical etching may be employed to etch through a remainder of the semiconductor layers to form the heterostructure micropillars, as illustrated in FIG. 10D.

FIG. 11A shows a heterostructure stack including non-p-type top layer(s) in this case, an n-type tunnel junction) on p-type semiconductor layer(s) (“p-side”). FIG. 11B shows formation of metal catalyst regions that can function also as a RIE mask layer. FIG. 11C shows metal-assisted chemical etching of the n-type tunnel junction, down to the p-type layers, which are etched with RIE, as shown in FIG. 11D. Finally, the remaining semiconductor layers are etched with metal-assisted chemical etching, as shown in FIG. 11E. In the above examples, RIE is applied only to nanoscale p-type semiconductor layer(s), and thus sidewall damage is kept to a minimum.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein.

Furthermore, the advantages described above are not necessarily the only advantages of the invention, and it is not necessarily expected that all of the described advantages will be achieved with every embodiment of the invention.

1. Light emitting diode (LED) structures for a microLED device, the light emitting diode structures comprising:
heterostructure micropillars on a substrate, each heterostructure micropillar comprising a stack of semiconductor layers separated by heterojunctions,
wherein sidewalls of the heterostructure micropillars are completely or substantially devoid of ion-induced defects.

2. The LED structures of claim 1, wherein some or all of the semiconductor layers comprise wide-bandgap semiconductor layers having a bandgap above about 3 eV.

3. The LED structures of claim 1, wherein the semiconductor layers include two or more group III-nitride semiconductors.

4. The LED structures of claim 3, wherein the two or more group III-nitride semiconductors comprise gallium nitride (GaN), aluminum gallium nitride (AlₓGa₁₋ₓN, or AlGaN), indium gallium nitride (InₓGa₁₋ₓN or InGaN), and/or indium gallium aluminum nitride (InₓGa_{y}Al_{1-x-y}N, or InGaAlN).

5. The LED structures of claim 1, wherein each of the heterostructure micropillars comprises a range of bandgaps.

6. The LED structures of claim 1, wherein the heterostructure micropillars include one or more multiple quantum wells (MQWs).

7. The LED structures of claim 1, wherein each of the heterostructure micropillars includes from 3 to 30 of the semiconductor layers.

8. The LED structures of claim 1, wherein each heterostructure micropillar has maximum width or diameter in a range from about 1 μm to about 20 μm.

9. The LED structures of claim 1, wherein from 100 to 600,000 heterostructure micropillars are arranged in an array on the substrate.

10. The LED structures of claim 1, wherein each heterostructure micropillar is configured to emit visible or ultraviolet (UV) light.

11. The LED structures of claim 1, wherein the substrate comprises a glass, polymer, metal, insulator, and/or semiconductor.

12. A microLED comprising the LED structures of claim 1.

13. A method of forming an array of light emitting diode (LED) structures, the method comprising:
providing a sample to be etched, the sample comprising a heterostructure stack with metal catalyst regions on a top surface thereof, the heterostructure stack comprising a plurality of semiconductor layers separated by heterojunctions;
exposing the sample to an etching solution or vapor; and
etching the semiconductor layers in a thickness direction between the metal catalyst regions, thereby forming an array of heterostructure micropillars, each covered with one of the metal catalyst regions.

14. The method of claim 13, further comprising, after forming the array of heterostructure micropillars, removing the metal catalyst regions.

15. The method of claim 13, further comprising, during the exposure to the etching solution or vapor, illuminating the sample with above-gap radiation.

16. The method of claim 15, wherein the above-gap radiation has a photon energy as high as and/or higher than bandgaps of all of the semiconductor layers,
wherein some or all of the semiconductor layers comprise wide bandgap semiconductor layers having bandgaps above about 3 eV.

17. The method of claim 15, wherein the above-gap radiation has a photon energy as high as and/or higher than bandgaps of only some of the semiconductor layers, whereby selective etching of the semiconductor layers having lower bandgaps occurs.

18. The method of claim 13, wherein providing the sample comprises:
epitaxially growing the semiconductor layers on a growth substrate;
depositing a metal catalyst layer on a top layer of the semiconductor layers; and
patterning the metal catalyst layer to form the metal catalyst regions.

19. The method of claim 13, wherein providing the sample comprises:
epitaxially growing the semiconductor layers on a growth substrate;
removing the heterostructure stack from the growth substrate by epitaxial lift-off;
flipping the heterostructure stack such that a bottom layer of the semiconductor layers becomes a top layer;
depositing a metal catalyst layer on the top layer; and
patterning the metal catalyst layer to form the metal catalyst regions.

20. The method of claim 13, wherein the etching solution or vapor comprises (1) an oxidant and (2) an acid or a base.

21. The method of claim 13, wherein the metal catalyst regions comprise a catalyst layer on a charge transfer layer.
